(19) United States
(12) Patent Application Publication
(10) Pub. No.: US 2026/0107347 A1
(43) Pub. Date: Apr. 16, 2026

(54) SUBSTRATE TREATMENT APPARATUS HAVING SUBSTRATE HEATER AND SUBSTRATE TREATMENT METHOD USING SAME

(71) Applicant: DEVICE CO., LTD., Chungcheongnam-do (KR)

(72) Inventor: Taek Youb Lee, Cheonan-si (KR)

(73) Assignee: DEVICE CO., LTD., Chungcheongnam-do (KR)

(21) Appl. No.: 19/000,433

(22) Filed: Dec. 23, 2024

(30) Foreign Application Priority Data
Oct. 16, 2024 (KR) 1020240141560

(51) Int. Cl. H05B 3/00; B08B 3/10; C23C 16/458

(52) U.S. Cl. CPC H05B 3/0038; B08B 3/10; C23C 16/4586

(57) ABSTRACT

The present disclosure relates to a substrate treatment apparatus including: a substrate-holding unit for holding and rotating a substrate; a treatment liquid feed unit for feeding treatment liquid to a top or underside of the substrate; a substrate heater located under the substrate and having a plurality of LEDs mounted thereon; and a blocking plate located on the substrate-holding unit, wherein a portion in a circumferential direction of the substrate heater about the center of the substrate is an unequally distributed LED portion where the LEDs have differential densities in a radial direction of the substrate and the remaining portion in the circumferential direction is an equally distributed LED portion where the LEDs are equally distributed in the radial direction of the substrate.

### CROSS REFERENCE TO RELATED APPLICATION OF THE DISCLOSURE

The present application claims the benefit of Korean Patent Application No. 10-2024-0141560 filed in the Korean Intellectual Property Office on Oct. 16, 2024, the entire contents of which are incorporated herein by reference.

### BACKGROUND OF THE DISCLOSURE

### Field of the Disclosure

The present disclosure relates to a substrate treatment apparatus having a substrate heater and a substrate treatment method using the same, more specifically to a substrate treatment apparatus having a substrate heater and a substrate treatment method using the same that are capable of allowing a temperature of a substrate heated through the substrate heater to be controlled partially in a radial direction of the substrate, thereby enabling an amount of treatment for the substrate to be relatively adjusted in the radial direction of the substrate.

### Background of the Related Art

Generally, a substrate treatment apparatus is an apparatus that performs, with the use of treatment liquids, various processes such as deposition, photolithography, etching, and cleaning for substrates such as semiconductor wafers, display substrate, optical disk substrates, magnetic disk substrates, photomask substrates, ceramic substrates, solar cell substrates, and the like.

Such a substrate treatment is carried out to feed treatment liquid to top or underside of a substrate to treat the substrate, while the substrate is rotating at a high speed in a state of being supportedly placed on top of a substrate-holding unit such as a chuck base (spin head).

In this case, a heating unit such as LEDs or a laser beam irradiation device is located under the substrate to allow the substrate to be heated to a given temperature, and next, if the heated substrate rotates so that it is subjected to a given treatment, a reaction occurs fast to reduce the amount of treatment liquid used. Further, the environmental contamination caused by the treatment liquid used is minimized, and the time required for the treatment is shortened to achieve improvement of productivity and a reduction in the quantity of electricity consumed.

FIG. 1 is a sectional view showing a conventional substrate treatment apparatus having a substrate heater, and a configuration of the conventional substrate treatment apparatus will be briefly described below.

The substrate treatment apparatus includes a chuck base 1 having chuck pins 5 located on top thereof, a substrate heater 3 located under the substrate W to heat a substrate W rotating, a bowl assembly 8 located around the chuck base 1, a treatment liquid feed unit 7 located above the substrate W fixed to the chuck pins 5 to spray treatment liquid onto top of the substrate W, and a back nozzle assembly 2 located on the underside of a central portion of the substrate W in such a way as to pass through the chuck base 1 to spray the treatment liquid onto the underside of the substrate W.

Further, the substrate treatment apparatus includes a blocking plate 4 made of quartz and located between the substrate heater 3 and the substrate W in such a way as to prevent the treatment liquid sprayed from the treatment liquid feed unit 7 or the back nozzle assembly 2 from entering the substrate heater 3 and thus causing a short circuit and to allow the radiation heat of the substrate heater 3 to be transferred smoothly to the substrate W.

When the substrate is treated, if a film quality of the substrate is measured just after previous process has been completed before another process starts, it is checked that the substrate is partially different in thickness in a radial direction thereof.

In this case, if the entire temperature of the substrate is uniformly kept by means of the substrate heater, the substrate is kept in a state of having partially different thicknesses even after the total processes of the substrate have been completed, which causes defects and greatly decreases yield.

In detail, the liquid fed to the substrate is applied uniformly in thickness to the substrate, in the state where the entire temperature of the substrate is uniformly kept, so that an amount of the liquid used is uniform over the entire surface of the substrate. Therefore, once the substrate is not uniform in thickness according to the positions of the substrate, such non-uniformity in thickness still remains even during post processes.

### SUMMARY OF THE DISCLOSURE

Accordingly, the present disclosure has been made in view of the above-mentioned problems occurring in the related art, and it is an object of the present disclosure to provide a substrate treatment apparatus having a substrate heater and a substrate treatment method using the same that are capable of allowing a temperature of a substrate heated through the substrate heater to be controlled partially in a radial direction of the substrate, so that an amount of treatment for the substrate is controlled according to the radial positions of the substrate, thereby reducing defects of the substrate and greatly improving yield thereof.

To accomplish the above-mentioned objects, according to one aspect of the present disclosure, there is provided a substrate treatment apparatus including: a substrate-holding unit for holding and rotating a substrate; a treatment liquid feed unit for feeding treatment liquid to a top or underside of the substrate held by the substrate-holding unit; a substrate heater located under the substrate and having a plurality of LEDs mounted thereon to heat the substrate; and a blocking plate located on the substrate-holding unit above the substrate heater in such a way as to allow light to pass therethrough toward the substrate and to prevent the treatment liquid from entering the substrate heater, wherein a portion in a circumferential direction of the substrate heater about the center of the substrate is an unequally distributed LED portion where the LEDs have differential densities in a radial direction of the substrate and the remaining portion in the circumferential direction is an equally distributed LED portion where the LEDs are equally distributed in the radial direction of the substrate.

According to the present disclosure, desirably, the unequally distributed LED portion may consist of a plurality of differential heating channel parts arranged in a circumferential direction of the substrate, and each of the differential heating channel parts may has the LEDs arranged to have differential densities in the radial direction of the substrate.

According to the present disclosure, desirably, the differential heating channel parts may allow the regions with the highest densities of the LEDs to be different from one another along the radial direction of the substrate.

According to the present disclosure, desirably, the unequally distributed LED portion may have a plurality of radial regions divided in the radial direction of the substrate, and as the radial regions with the highest densities of the LEDs on the differential heating channel parts are distant from the center toward the edge of the substrate, the number of LEDs may gradually increase.

According to the present disclosure, desirably, the number of differential heating channel parts may correspond to the number of radial regions divided, and the respective differential heating channel parts may have the radial regions having the highest densities of the LEDs, the respective radial regions having the highest densities of the LEDs being different from one another.

According to the present disclosure, desirably, the differential heating channel parts may be arranged adjacent to one another.

According to the present disclosure, desirably, the equally distributed LED portion and the unequally distributed LED portion may be separated from each other, and the equally distributed LED portion and the unequally distributed LED portion may include at least one or more heating units along the circumferential direction of the substrate.

According to the present disclosure, desirably, the plurality of heating units constituting the equally distributed LED portion and the unequally distributed LED portion may be equally divided and arranged, while each of the plurality of heating units having a plurality of control channels, and each of the plurality of control channels is connected to the LEDs of the same size and number.

According to the present disclosure, desirably, each of the control channels of the plurality of heating units constituting the unequally distributed LED portion may be included in each of the differential heating channel parts.

According to the present disclosure, desirably, if the output values of the LEDS on the unequally distributed LED portion of the substrate heater increase or decrease, the output values of the LEDs on the equally distributed LED portion may increase or decrease contrarily to the output values of the LEDs on the unequally distributed LED portion.

According to the present disclosure, desirably, the output values of the LEDs on one of the plurality of differential heating channel parts constituting the unequally distributed LED portion may increase or decrease with respect to a predetermined set value, the remaining differential heating channel parts may be kept to the predetermined set value, and the output values of the LEDs on the equally distributed LED portion may increase or decrease contrarily to the output values of the LEDs on the differential heating channel parts.

To accomplish the above-mentioned objects, according to another aspect of the present disclosure, there is provided a substrate treatment method using the substrate treatment apparatus, the method including the steps of: holding and rotating the substrate by means of the substrate-holding unit and feeding the treatment liquid to the top or underside of the substrate, while heating the substrate by means of the substrate heater; and if the output values of the LEDS on the unequally distributed LED portion constituting the substrate heater increase or decrease, the output values of the LEDS on the equally distributed LED portion increase or decrease contrarily to the output values of the LEDs on the unequally distributed LED portion.

According to the present disclosure, desirably, the output values of the LEDs on one of the plurality of differential heating channel parts constituting the unequally distributed LED portion may increase or decrease with respect to a predetermined set value, the remaining differential heating channel parts may be kept to the predetermined set value, and the output values of the LEDs on the equally distributed LED portion may increase or decrease contrarily to the output values of the LEDs on the differential heating channel parts.

### BRIEF DESCRIPTION OF THE DRAWINGS

The above and other objects, features and advantages of the present disclosure will be apparent from the following detailed description of the embodiments of the disclosure in conjunction with the accompanying drawings, in which:

FIG. 1 is a longitudinal sectional view showing a conventional substrate treatment apparatus having a substrate heater;

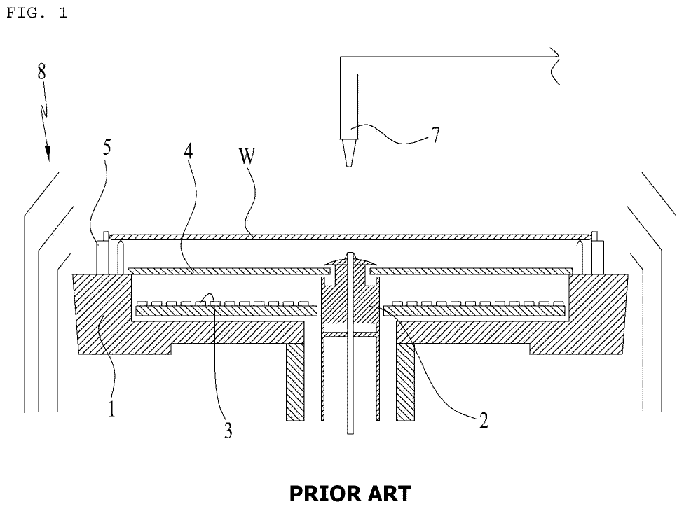

FIG. 2 is a longitudinal sectional view showing a substrate treatment apparatus having a substrate heater according to the present disclosure;

FIG. 3 is a plan view showing the substrate heater of the substrate treatment apparatus according to the present disclosure;

FIG. 4 is a graph showing the outputs of LEDs on four differential heating channel parts and an equally distributed LED portion and the temperature distribution of a substrate in the radial direction of the substrate to allow the entire substrate to have uniform temperature distribution through the substrate treatment apparatus according to the present disclosure;

FIG. 5 is a graph showing the outputs of the LEDs on the four differential heating channel parts and the equally distributed LED portion and the temperature distribution of the substrate in the radial direction of the substrate to allow a relatively high temperature to appear on the center of the substrate through the substrate treatment apparatus according to the present disclosure; and

FIG. 6 is a graph showing the outputs of the LEDS on the four differential heating channel parts and the equally distributed LED portion and the temperature distribution of the substrate in the radial direction of the substrate to allow a relatively high temperature to appear near the edge of the substrate through the substrate treatment apparatus according to the present disclosure.

### DETAILED DESCRIPTION OF THE PREFERRED EMBODIMENT

Hereinafter, an embodiment of the present disclosure will be explained in detail with reference to the attached drawings.

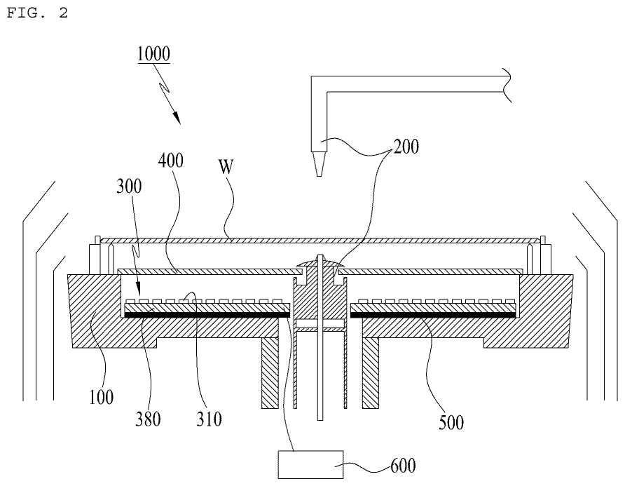

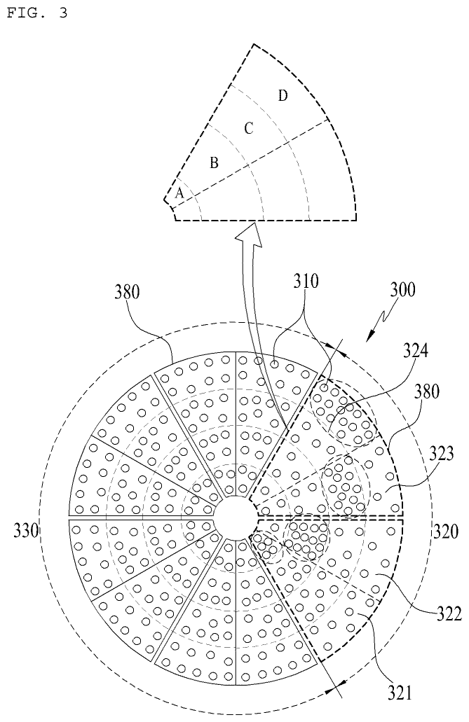

As shown in FIGS. 2 and 3, a substrate treatment apparatus 1000 according to the present disclosure includes: a substrate-holding unit 100 for holding and rotating a substrate W; a treatment liquid feed unit 200 for feeding treatment liquid 210 to a top or underside of the substrate W held by the substrate-holding unit 100; a substrate heater 300 located under the substrate W and having a plurality of LEDS 310 mounted thereon to heat the substrate W; and a blocking plate 400 located on the substrate-holding unit 100 above the substrate heater 300 in such a way as to allow light to pass therethrough toward the substrate W and to prevent the treatment liquid from entering the substrate heater 300, wherein a portion in a circumferential direction of the substrate heater 300 about the center of the substrate W is an unequally distributed LED portion 320 where the plurality of LEDs 310 have differential densities in a radial direction of the substrate W and the remaining portion in the circumferential direction of the substrate heater 300 is an equally distributed LED portion 330 where the plurality of LEDs 310 are equally distributed.

As shown in FIG. 3, the unequally distributed LED portion 320 is defined by an arrow with a thick dotted line, and the equally distributed LED portion 330 by an arrow with a solid line.

In the drawings, further, the neighboring LEDs 310 of the equally distributed LED portion 330 look somewhat different intervals from one another, but they actually have the same intervals as one another in such a way as to have constant densities in radial regions having given length in a radial direction.

Further, a heat sink 500 is located on the underside of the substrate heater 300 to emit the heat generated from the substrate heater 300.

Like this, the unequally distributed LED portion 320 where the plurality of LEDs 310 have differential densities in the radial direction of the substrate W is formed on a portion in the circumferential direction of the substrate heater 300 about the center of the substrate W, so that output values of some of the plurality of LEDS 310 arranged in the unequally distributed LED portion 320 are different from a predetermined set value, thereby allowing a substrate-heating temperature to be controlled differently along the radial direction of the substrate W.

In this case, the predetermined set value means a set value for uniformly keeping a temperature of the entire substrate W at a value.

If the substrate-heating temperature is controlled differently along the radial direction of the substrate 3 according to deviations in radial thickness of the substrate W that are generated after the process just before the substrate treatment has been completed, an amount of treatment is varied along the radial direction of the substrate W, thereby preventing the reduction of yield due to size defects.

Further, the unequally distributed LED portion 320 consists of a plurality of differential heating channel parts 321 to 324 arranged in the circumferential direction of the substrate heater 300, and in this case, the differential heating channel parts 321 to 324 have the LEDs 310 arranged to have differential densities along the radial direction of the substrate W respectively.

As shown in FIG. 3, the differential heating channel parts 321 to 324 are defined by dotted lines.

As the outputs of the LEDs 310 mounted on any one of the differential heating channel parts 321 to 324 increase or decrease, an amount of treatment is controlled along the radial direction of the substrate W.

The LEDS 310 mounted on the differential heating channel parts 321 to 324 can be connected in series with one another, and thus, if power is connected incompletely to any one of the LEDs 310, the total LEDs 310 of the differential heating channel part having the corresponding LED 310 are not turned on.

However, it is possible to adopt other power connection types.

As shown in FIG. 3, the unequally distributed LED portion 320 is divided into a plurality of radial regions A, B, C, and D from the center of the substrate W in the radial direction of the substrate W, and the densities of the LEDs 310 along the plurality of radial regions A, B, C, and D may be differential in each of the differential heating channel parts 321 to 324.

As shown, if the plurality of radial regions A, B, C, and D desirably extend in the circumferential direction of the substrate W, they are present in the form of circular loops about the center of the substrate W, but they may extend in the form of regular polygons or polygons.

In the circular loops case, the extending portions of the plurality of radial regions A, B, C, and D are defined by circular dotted lines.

As shown, further, the four radial regions A, B, C, and D are arranged sequentially from the center toward the edge of the substrate W, but of course, two, three, or five radial regions may be arranged.

In this case, the differential heating channel parts 321 to 324 allow the regions with the highest densities of the LEDs 310 to be arranged differently along the radial direction of the substrate W respectively.

If power is supplied to the respective differential heating channel parts 321 to 324, the regions with the highest densities of the LEDs 310 along the radial direction of the substrate W emit the highest heat.

If the unequally distributed LED portion 320 is divided into the plurality of radial regions A, B, C, and D from the center of the substrate W in the radial direction of the substrate W, the differential heating channel parts 321 to 324 allow the radial regions A, B, C, and D with the highest densities of the LEDS 310 to be arranged differently from one another along the radial direction of the substrate W.

That is, the differential heating channel part 321 has the highest density of the LEDs 310 on the radial region A, the differential heating channel part 322 has the highest density of the LEDs 310 on the radial region B, the differential heating channel part 323 has the highest density of the LEDs 310 on the radial region C, and the differential heating channel part 324 has the highest density of the LEDs 310 on the radial region D.

Under such a configuration, the outputs of the LEDs 310 arranged on the differential heating channel part 321 increase or decrease to raise or lower a temperature of the circumferential region of the substrate W passing through the radial region A.

In the same manner as above, the outputs of the LEDs 310 arranged on the differential heating channel part 324 increase or decrease to raise or lower a temperature of the circumferential region of the substrate W passing through the radial region D.

Further, the radial regions A, B, C, and D with the highest densities of the LEDS 310 on the respective differential heating channel parts 321 to 324 are configured to allow the number of LEDS 310 to gradually increase from the center toward the edge of the substrate W, so that relatively high densities of the LEDs 310 are desirably kept, irrespective of the positions of the radial regions A, B, C, and D with the highest densities of the LEDs 310.

In other words, the number of LEDs 310 arranged on the radial region A having the highest density on the differential heating channel part 321 is smaller than the number of LEDs 310 arranged on the radial region D having the highest density on the differential heating channel part 324.

Further, as shown in FIG. 3, the number of differential heating channel parts 321 to 324 corresponds to the number of radial regions A, B, C, and D, and the respective differential heating channel parts 321 to 324 have their respective radial regions A, B, C, and D having the highest densities of the LEDs 310, which are different from one another.

The differential heating channel parts 321 to 324 are arranged adjacent to one another in the circumferential direction of the substrate W in such a way as to be controlled easily through control channels, but it is possible that they are arranged alternately with the equally distributed LED portion 330.

The equally distributed LED portion 330 and the unequally distributed LED portion 320 constituting the substrate heater 300 are separated from each other, and each of them may include at least one or more heating units 380 along the circumferential direction of the substrate W.

In this case, the heating units 380 can be provided as printed circuit boards PCB on which the plurality of LEDs 310 are mounted.

Under such a configuration, if any one of the LEDs 310 is abnormal, only the heating unit 380 on which the corresponding LED 310 is mounted is replaced with new one, so that a replacement cost is more reduced when compared with the configuration having a single heating unit.

Further, the plurality of heating units 380 constituting the equally distributed LED portion 330 and the unequally distributed LED portion 320 are equally divided and arranged, while each of the plurality of heating units, they have their respective control channels, and each of the plurality of control channels is connected to the LEDs of the same size and number. The LEDs 310 of the same size and number are connected to the respective control channels.

In the drawings, twelve control channels have their respective 24 LEDs 310 mounted thereon, but the number of LEDS 310 mounted on each control channel may be arbitrarily determined.

Under such a configuration, controllers 600 connected to the respective control channels have the same capacity as one another, so that the maintenance for the controllers 600 is performed with easiness and the cost for the maintenance is reduced.

Further, each of the control channels of the heating units 380 constituting the unequally distributed LED portion 320 are included in each of the differential heating channel parts 321 to 324.

If the output values of the LEDS 310 on the unequally distributed LED portion 320 increase or decrease to raise or lower the temperature of the substrate W corresponding to any one of the plurality of radial regions A, B, C, and D, desirably, the output values of the LEDs 310 on the equally distributed LED portion 330 increase or decrease contrarily to the output values of the LEDs 310 on the unequally distributed LED portion 320.

This is because the output values of the LEDs 310 increase or decrease on the radial regions having the highest densities of the LEDs 310 and they increase or decrease on the remaining radial regions excepting the radial regions having the highest densities of the LEDs 310, when the output values of the LEDS 310 on the unequally distributed LED portion 320 constituting the substrate heater 300 increase or decrease, so that the temperature of the substrate W corresponding to the radial regions excepting the radial regions having the highest densities of the LEDS 310 somewhat increases or decreases. To offset the increasing or decreasing temperature, the output values of the LEDs 310 on the equally distributed LED portion 330 increase or decrease contrarily to the output values of the LEDs 310 on the unequally distributed LED portion 320.

In detail, the output values of the LEDs 310 on one of the plurality of differential heating channel parts 321 to 324 constituting the unequally distributed LED portion 320 increase or decrease with respect to a predetermined set value, the remaining differential heating channel parts are kept to the predetermined set value, and the output values of the LEDs 310 on the equally distributed LED portion 330 increase or decrease contrarily to the output values of the LEDs 310 on the differential heating channel parts 321 to 324.

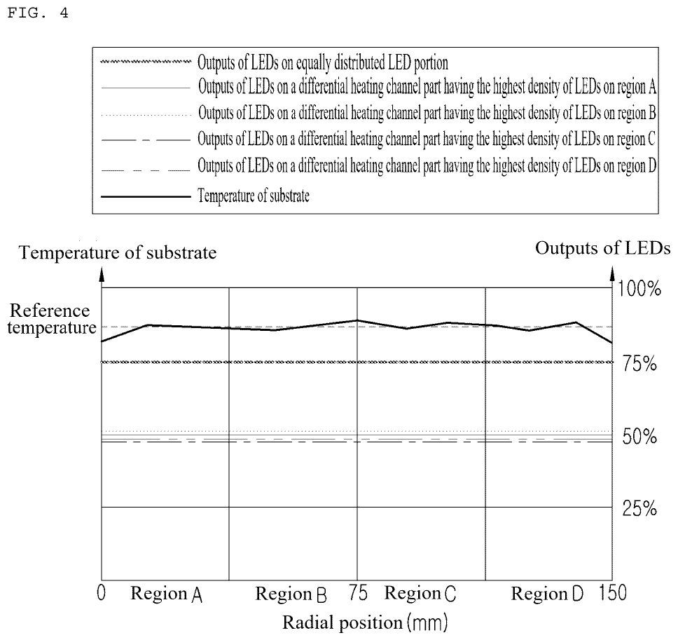

FIGS. 4 to 6 are graphs showing the temperature distribution of the substrate W according to changes in heating distribution of the substrate heater 300 on the substrate treatment apparatus 1000 according to the present disclosure.

As shown, the unequally distributed LED portion 320 is divided into four radial regions A, B, C, and D in the radial direction of the substrate W, and the four differential heating channel parts 321 to 324 have the radial regions A, B, C, and D respectively on which the highest densities of the LEDs 310 are different from one another in the radial direction of the substrate W.

FIG. 4 shows a predetermined set values of outputs of the LEDs 310 on the four differential heating channel parts 321 to 324 and the equally distributed LED portion 330 and the temperature distribution of the substrate W in the radial direction of the substrate W to allow the substrate W to have entirely equal temperature distribution.

As shown, the outputs of the LEDs 310 on the four differential heating channel parts 321 to 324 are set to 50% of maximum outputs (100%), and the outputs of the LEDS 310 on the equally distributed LED portion 330 are set to 75% of the maximum outputs (100%). In this case, the substrate W has an equal temperature over the range from the region A close to the center of the substrate W to the region D close to the edge of the substrate W in the radial direction of the substrate W.

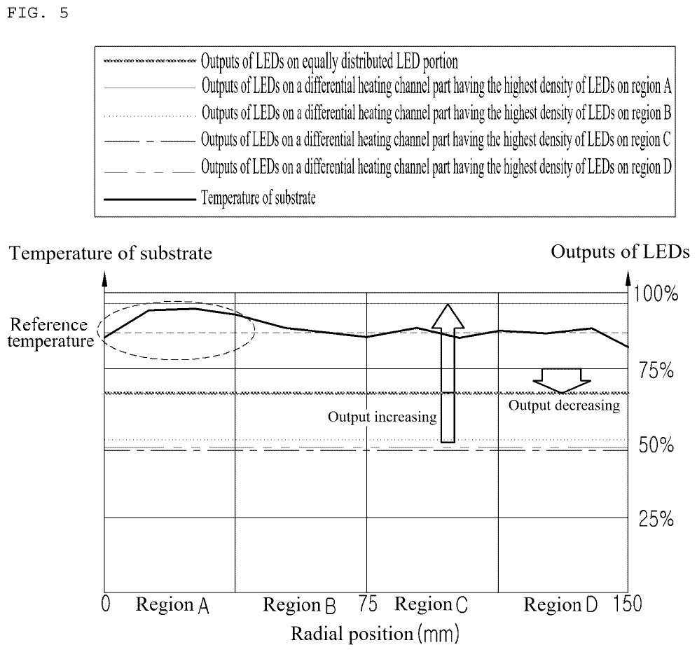

FIG. 5 shows the outputs of the LEDs 310 on the four differential heating channel parts 321 to 324 and the equally distributed LED portion 330 and the temperature distribution of the substrate W in the radial direction of the substrate W to allow a relatively high temperature to appear on the center of the substrate W.

As shown, the outputs of the LEDS 310 on the differential heating channel part 321 having the highest density of the LEDs 310 on the region A among the four differential heating channel parts 321 to 324 increase to outputs close to the 100% maximum outputs, and the outputs of the LEDs 310 on the remaining three differential heating channel parts 322, 323, and 324 are set to 50% of the maximum outputs as the predetermined Set values, and the outputs of the LEDs 310 on the equally distributed LED portion 330 are set to about 65% which is lower than the predetermined set values. In this case, the substrate W corresponding to the region A increases in temperature, and the substrate W has an equal temperature over the range from the region B to the region D in the radial direction of the substrate W.

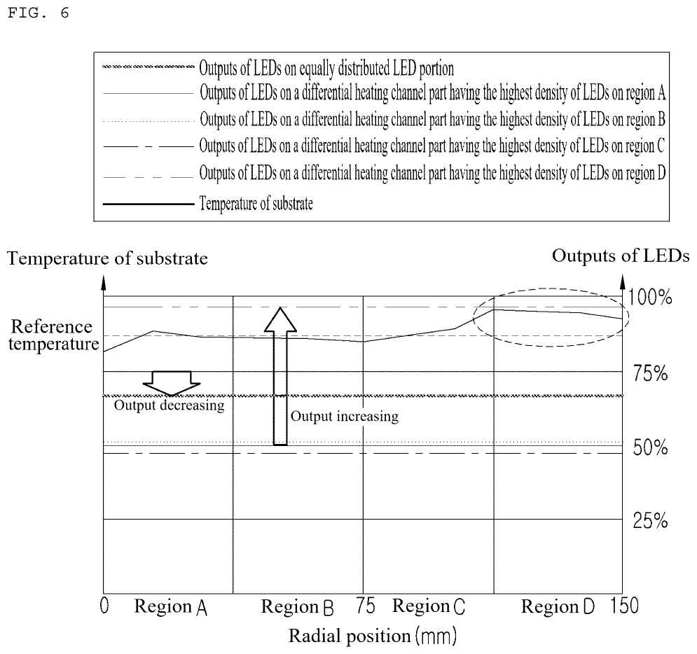

FIG. 6 shows the outputs of the LEDs 310 on the four differential heating channel parts 321 to 324 and the equally distributed LED portion 330 and the temperature distribution of the substrate W in the radial direction of the substrate W to allow a relatively high temperature to appear on the edge of the substrate W.

As shown, the outputs of the LEDS 310 on the differential heating channel part 324 having the highest density of the LEDs 310 on the region D among the four differential heating channel parts 321 to 324 increase to the outputs close to the 100% maximum outputs, and the outputs of the LEDs 310 on the remaining three differential heating channel parts 321, 322, and 323 are set to 50% of the maximum outputs as the predetermined set values, and the outputs of the LEDS 310 on the equally distributed LED portion 330 are set to about 65% which is lower than the predetermined set values. In this case, the substrate W corresponding to the region D increases in temperature, and the substrate W has an equal temperature over the range from the region A to the region C in the radial direction of the substrate W.

FIGS. 5 and 6 show the examples where some regions of the substrate W increase in temperature, but to decrease temperatures on some regions of the substrate W, operations are carried out contrarily to the operations as described with reference to FIGS. 5 and 6.

To allow a relatively low temperature to appear on the center of the substrate W, for example, the outputs of the LEDs 310 on the differential heating channel part 321 having the highest density of the LEDs 310 on the region A among the four differential heating channel parts 321 to 324 decrease to outputs lower than 50% which is the predetermined set values, and the outputs of the LEDS 310 on the remaining three differential heating channel parts 322, 323, and 324 are set to 50% outputs as the predetermined set values, and the outputs of the LEDs 310 on the equally distributed LED portion 330 are set to about 85% which is higher than the predetermined set values.

The substrate treatment method using the substrate treatment apparatus according to the present disclosure includes the steps of holding and rotating the substrate W by means of the substrate-holding unit 100 and feeding the treatment liquid to the top or underside of the substrate W, while heating the substrate W by means of the substrate heater 300; and if the output values of the LEDs 310 on the unequally distributed LED portion 320 constituting the substrate heater 300 increase or decrease, the output values of the LEDs 310 on the equally distributed LED portion 330 increase or decrease contrarily to the output values of the LEDs 310 on the differential heating channel parts 320, whereby the substrate W is adjusted in temperature on a given radial region thereof.

In detail, the output values of the LEDs 310 on one of the plurality of differential heating channel parts 321 to 324 constituting the unequally distributed LED portion 320 increase or decrease with respect to the predetermined set values, the output values of the LEDS 310 on the remaining three differential heating channel parts are kept to the predetermined set values, and the output values of the LEDs 310 on the equally distributed LED portion 330 which a plurality of LEDs 310 are evenly distributed increase or decrease contrarily to the output values of the LEDs 310 of the corresponding differential heating channel part.

As described above, the substrate treatment apparatus and method according to the present disclosure is configured to allow the unequally distributed LED portion where the plurality of LEDs have differential densities in the radial direction of the substrate to be formed on a portion in the circumferential direction of the substrate heater about the center of the substrate, so that the output values of at least a portion of the plurality of LEDS arranged on the unequally distributed LED portion are set differently from predetermined set values, thereby allowing a substrate-heating temperature to be controlled differently along the radial direction of the substrate, and if the substrate-heating temperature is controlled differently along the radial direction of the substrate according to deviations in radial thickness of the substrate that are generated after the process just before the substrate treatment has been completed, amounts of treatment are varied along the radial direction of the substrate, thereby preventing the reduction of a yield due to size defects.

Further, the substrate treatment apparatus and method according to the present disclosure is configured to allow the equally distributed LED portion and the unequally distributed LED portion constituting the substrate heater to be separated from each other as at least one or more heating units along the circumferential direction of the substrate heater, so that if any one of the LEDs is abnormal, only the heating unit on which the corresponding LED is mounted is replaced with new one, thereby more reducing a replacement cost when compared with the configuration having a single heating unit.

Besides, the substrate treatment apparatus and method according to the present disclosure is configured to allow the plurality of heating units constituting the equally distributed LED portion and the unequally distributed LED portion to be equally divided and arranged, while each of the plurality of heating units having a plurality of control channels, and each of the plurality of control channels is connected to the LEDs of the same size and number, so that capacities of controllers connected to the respective differential heating channel parts are the same as one another, thereby allowing the maintenance of the controllers to be more easily performed and reducing the cost for the maintenance.

The present disclosure may be modified in various ways and may have several exemplary embodiments. It is therefore intended that the scope of the disclosure be limited not by this detailed description, but rather by the claims appended hereto, and it should be understood that the disclosure covers all the modifications, equivalents, and replacements within the idea and technical scope of the disclosure.

What is claimed is:

1. A substrate treatment apparatus comprising:
a substrate-holding unit for holding and rotating a substrate;
a treatment liquid feed unit for feeding treatment liquid to a top or underside of the substrate held by the substrate-holding unit;
a substrate heater located under the substrate and having a plurality of LEDs mounted thereon to heat the substrate; and
a blocking plate located on the substrate-holding unit above the substrate heater in such a way as to allow light to pass therethrough toward the substrate and to prevent the treatment liquid from entering the substrate heater,
wherein a portion in a circumferential direction of the substrate heater about the center of the substrate is an unequally distributed LED portion where the LEDS have differential densities in a radial direction of the substrate and the remaining portion in the circumferential direction is an equally distributed LED portion where the LEDs are equally distributed in the radial direction of the substrate.

2. The substrate treatment apparatus according to claim 1, wherein the unequally distributed LED portion consists of a plurality of differential heating channel parts arranged in a circumferential direction of the substrate, and each of the differential heating channel parts has the LEDs arranged to have differential densities in the radial direction of the substrate.

3. The substrate treatment apparatus according to claim 2, wherein the differential heating channel parts allow the regions with the highest densities of the LEDs to be different from one another along the radial direction of the substrate.

4. The substrate treatment apparatus according to claim 3, wherein the unequally distributed LED portion has a plurality of radial regions divided in the radial direction of the substrate, and as the radial regions with the highest densities of the LEDs on the differential heating channel parts are distant from the center toward the edge of the substrate, the number of LEDS gradually increases.

5. The substrate treatment apparatus according to claim 4, wherein the number of differential heating channel parts corresponds to the number of radial regions divided, and the respective differential heating channel parts have the radial regions having the highest densities of the LEDs, the respective radial regions having the highest densities of the LEDs being different from one another.

6. The substrate treatment apparatus according to claim 2, wherein the differential heating channel parts are arranged adjacent to one another.

7. The substrate treatment apparatus according to claims 2, wherein the equally distributed LED portion and the unequally distributed LED portion are separated from each other, and the equally distributed LED portion and the unequally distributed LED portion comprise at least one or more heating units along the circumferential direction of the substrate.

8. The substrate treatment apparatus according to claim 7, wherein the plurality of heating units constituting the equally distributed LED portion and the unequally distributed LED portion are equally divided and arranged, while each of the plurality of heating units having a plurality of control channels, and each of the plurality of control channels is connected to the LEDs of the same size and number.

9. The substrate treatment apparatus according to claim 8, wherein each of the control channels of the plurality of heating units constituting the unequally distributed LED portion is included in each of the differential heating channel parts.

10. The substrate treatment apparatus according to claims 2, wherein if the output values of the LEDs on the unequally distributed LED portion of the substrate heater increase or decrease, the output values of the LEDS on the equally distributed LED portion increase or decrease contrarily to the output values of the LEDs on the unequally distributed LED portion.

11. The substrate treatment apparatus according to claim 10, wherein the output values of the LEDs on one of the plurality of differential heating channel parts constituting the unequally distributed LED portion increase or decrease with respect to a predetermined set value, the remaining differential heating channel parts are kept to the predetermined set value, and the output values of the LEDs on the equally distributed LED portion increase or decrease contrarily to the output values of the LEDs on the differential heating channel parts.

12. A substrate treatment method using the substrate treatment apparatus according to claims 2, the method comprising the steps of:
holding and rotating the substrate by means of the substrate-holding unit and feeding the treatment liquid to the top or underside of the substrate, while heating the substrate by means of the substrate heater; and
if the output values of the LEDs on the unequally distributed LED portion constituting the substrate heater increase or decrease, the output values of the LEDs on the equally distributed LED portion increase or decrease contrarily to the output values of the LEDs on the unequally distributed LED portion.

13. The substrate treatment method according to claim 12, wherein the output values of the LEDs on one of the plurality of differential heating channel parts constituting the unequally distributed LED portion increase or decrease with respect to a predetermined set value, the remaining differential heating channel parts are kept to the predetermined set value, and the output values of the LEDs on the equally distributed LED portion increase or decrease contrarily to the output values of the LEDs on the differential heating channel parts.
